(19) United States
(12) Patent Application Publication
(10) Pub. No.: US 2010/0171506 A1
(43) Pub. Date: Jul. 8, 2010

(54) Explosion-proof detector assembly for a flame ionization detector (FID)

(76) Inventors: James Norgaard, Marblehead, MA (US); Gary Richard, Brookline, MA (US); Joseph A. Rebeiro, Freetown, MA (US)

Correspondence Address: Iandiorio Teska & Coleman, 260 Bear Hill Road, Waltham, MA, 02451, US

(21) Appl. No.: 12/592,145

(22) Filed: Nov. 19, 2009

Related U.S. Application Data
(60) Provisional application No. 61/200,269, filed on Nov. 26, 2008.

(51) Int. Cl. G01N 27/62; G01R 1/04

(52) U.S. Cl. 324/468; 324/156

(57) ABSTRACT

An explosion-proof detector assembly for a flame ionization detector (FID) including an explosion-proof detector assembly enclosure configured to house the FID therein. A vent assembly coupled to the assembly enclosure includes a sintered metal frit configured to allow exhaust generated by the FID to vent from the detector assembly enclosure. A hydrogen supply line assembly coupled to the assembly enclosure includes a sintered metal frit configured to deliver a supply of hydrogen to the FID. A sample line assembly coupled to the enclosure includes a sintered metal frit configured to deliver a sample gas to the FID. A pressure relief assembly coupled to the assembly enclosure includes a sintered metal frit configured to ensure the pressure inside the detector assembly enclosure does not exceed a predetermined pressure. The sintered metal frit of the vent assembly, the hydrogen supply line assembly, the sample line assembly, and the pressure relief assembly are each configured to prevent a flame generated by the FID from contacting an explosive atmosphere outside the assembly enclosure, dissipate heat such that the temperature thereof does not exceed a predetermined temperature, and create an explosion-proof seal. An electrical conduit assembly is configured to house a plurality of data communication and power wires and is configured to prevent a flame generated by the FID from contacting an explosive atmosphere outside the detector assembly enclosure, dissipates heat such that the temperature of all surfaces thereof does not exceed a predetermined temperature, and creates an explosion-proof seal.

### RELATED APPLICATIONS

This application claims benefit of and priority to U.S. Provisional Application Ser. No. 61/200,269 filed Nov. 26, 2008 under 35 U.S.C. §§119, 120, 363, 365, and 37 C.F.R. §1.55 and §1.78, incorporated herein by this reference.

### FIELD OF THE INVENTION

This invention relates to an explosion-proof detector assembly for a flame ionization detection detector (FID).

### BACKGROUND OF THE INVENTION

A FID device is one type of emissions monitoring device used in leak detection and repair applications (LDAR), landfill gas monitoring, environmental assessments, and the like. The FID device can be used to detect volatile organic compounds (VOCs) and/or hazardous organic compounds produced from petro-chemical facilities, chemical plants, paint facilities, and similar type facilities which emit VOCs.

A typical FID device can detect VOCs ranging from about 0.1 ppm to about 100,000 ppm. The FID device is typically a multi-piece instrument which includes at least a main body where the FID is housed, electronic circuitry, and a hand held probe for sampling the VOCs. The FID device is typically portable, battery powered, and has all required consumables on-board. The main body is typically worn in a backpack configuration or carried by a handle or a shoulder strap. The FID itself utilizes a hydrogen flame contained within the chamber of the FID. A sample is drawn into the FID chamber where it encounters the hydrogen flame. VOCs (if present) are ionized when they encounter the flame. The burning of VOCs in the sample causes the temporary generation of ions that affect a charge differential that is measured by electronic circuitry.

In the United States, LDAR monitoring is governed by Federal Reference Method (FRM) 21 Determination of Volatile Organic Compound Leaks, incorporated by reference herein. FRM 21 contains a major requirement that affects the FID device. The requirement as described in Section 6.6 of Section 6.0 requires any device that includes a FID must be intrinsically safe (IS) for operation in explosive atmospheres.

In the United States, a FID device needs to be certified as IS before it can be used in a hazardous environment. To be certified as IS, the FID device needs to meet the requirements of at least Underwriters Laboratory (UL) 913 standard for safety for intrinsically safe apparatus for use in class I, II, and II, division 1, hazardous (classified) locations, Fifth Edition, dated February, 1997, and Underwriters Laboratory UL 1203 standard for safety of explosion-proof and dust-ignition-proof electrical equipment for use in hazardous (classified) locations, Third Edition, dated Sep. 7, 2000, both incorporated by reference herein.

Underwriters Laboratory is a nationally approved testing laboratory which sets the standards and gives IS certification to FID devices. OSHA is the governmental agency which monitors the UL standards and accredits national laboratories, such as Underwriters Laboratories, Intertek, and the like, as competent and capable of evaluating a FID device to determine if it meets UL 913 and/or UL 1203. If the FID device meets such standards, the nationally recognized laboratory provides IS certification.

In Europe, a FID device is also required to be certified intrinsically safe under the ATEX directive: “Council Directive 94/9/EC of the European Parliament and the Council of 23 Mar. 1994 on the Approximation of the Laws of the Member States concerning Equipment and Protective systems intended for use in Potentially Explosive Atmospheres”, incorporated by reference herein.

In order to be certified as IS, conventional emissions monitoring devices built ten or fifteen years ago were subject to much less demanding requirements. Today, a FID device which utilizes a FID that has two open sources of possible ignition to an explosive environment (the ignitor and the flame itself) is subject of the far stricter and more aggressive safety issues as mandated by UL 913 and/or UL 1203. Therefore, the FID needs to be housed in an explosion proof enclosure which prevents the flame from contacting the explosive environment and also ensures all surfaces of the explosion-proof detector assembly that are in contact with the environment meet the T4 temperature rating of UL 913.

### BRIEF SUMMARY OF THE INVENTION

This invention features an explosion-proof detector assembly for a flame ionization detector (FID) including an explosion-proof detector assembly enclosure configured to house the FID therein. A vent assembly coupled to the assembly enclosure includes a sintered metal frit configured to allow exhaust generated by the FID to vent from the detector assembly enclosure. A hydrogen supply line assembly coupled to the assembly enclosure includes a sintered metal frit configured to deliver a supply of hydrogen to the FID. A sample line assembly coupled to the enclosure includes a sintered metal frit configured to deliver a sample gas to the FID. A pressure relief assembly coupled to the assembly enclosure includes a sintered metal frit configured to ensure the pressure inside the detector assembly enclosure does not exceed a predetermined pressure. The sintered metal frit of the vent assembly, the hydrogen supply line assembly, the sample line assembly, and the pressure relief assembly are each configured to prevent a flame generated by the FID from contacting an explosive atmosphere outside the assembly enclosure, dissipate heat such that the temperature thereof does not exceed a predetermined temperature, and create an explosion-proof seal. An electrical conduit assembly is configured to house a plurality of data communication and power wires and is configured to prevent a flame generated by the FID from contacting an explosive atmosphere outside the detector assembly enclosure, dissipates heat such that the temperature of all surfaces thereof does not exceed a predetermined temperature, and creates an explosion-proof seal.

In one embodiment, the explosion-proof detector assembly may be configured to meet the standards of UL 913 and/or UL 1203. The detector assembly enclosure may include a plurality of openings each having internal threads. The vent assembly may include a collar configured to house the sintered metal frit of the vent assembly therein. The vent assembly may include an adapter including internal threads for mating with external threads of the collar and external threads for mating with internal threads of one of the plurality of openings of the detector assembly enclosure. The external threads of the collar, the internal and external threads of the adaptor, and the internal threads of one of the plurality of openings of the detector assembly enclosure may each have a predetermined class of fit, a predetermined number of threads, and a predetermined thread depth configured to meet the requirements of UL 913 and UL 1203. The sintered metal frit of the vent assembly may be configured with a predetermined pore size, dimension, and flow rate to meet the standards of UL 913 and/or UL 1203. The hydrogen supply line assembly may include a fitting configured to house the sintered metal frit of the hydrogen supply line assembly therein. The fitting assembly may include a external threads for mating with internal threads of one of the plurality of openings of the detector assembly enclosure. The external threads of the fitting and the internal threads of the one of the plurality of openings of the detector assembly enclosure may each have a predetermined class of fit, number of threads, and thread depth configured to meet the standards of UL 913 and/or UL 1203. The sintered metal fit of the hydrogen supply line assembly may be configured with a predetermined pore size, dimension, and flow rate to meet the standards of UL 913 and/or UL 1203. The sample line assembly may include a fitting having internal threads configured to house the sintered metal thread therein. The fitting may include external threads for mating with internal threads of one of the plurality of openings of the detector assembly enclosure. The external threads of the fitting and the internal threads of the one of the plurality of openings of the detector assembly enclosure may each have a predetermined class of fit, number of threads, and thread depth configured to meet the standards of UL 913 and/or UL 1203. The sintered metal frit of the sample line assembly may be configured with a predetermined pore size, dimension, and flow rate to meet the standards of UL 913 and/or UL 1203. The electrical conduit assembly may include a sleeve coupled to the detector assembly enclosure and a wire spacer for spreading a plurality of data communication and power wires in the sleeve and a composite of one predetermined type on the exterior atmospheric side of the detector assembly enclosure and another composite of another predetermined type on the interior side of the detector assembly enclosure configured to meet the standards of UL 913 and UL 1203. The composite on the interior side of the detector assembly enclosure may be configured to prevent moisture inside the enclosure from damaging the composite on the exterior atmospheric side of the detector assembly enclosure. The spacer may be configured to prevent arcing of the data communication and power wires in the event of one or more fault conditions. The sleeve of the electrical conduit assembly may include external threads for mating with the internal threads of one of the plurality of openings of the detector assembly enclosure. The external threads of the sleeve and the internal threads of the one of the plurality of openings of the detector assembly enclosure may each have a predetermined class of fit, number of threads, and thread depth configured to meet the standards of UL 913 and/or UL 1203. The detector assembly enclosure may include a mechanical assembly opening and a cover plate securably attached thereto. The mechanical assembly opening may include internal threads and the cover plate may include external threads for mating with the internal threads of the mechanical opening. The internal threads of the mechanical assembly opening and the external threads of the cover may each have a predetermined class of fit, number of threads, and thread depth configured to meet the standards of UL 913 and/or UL 1203. The detector assembly enclosure may have a minimum predetermined thickness configured to provide an explosion-proof seal and configured to meet the standards of UL 913 and/or UL 1203. The cover may have a minimum predetermined thickness configured to provide an explosion-proof seal and configured to meet the standards of UL 913 and/or UL 1203. The detector assembly enclosure may be made of a non-ferrous material. The non-ferrous material may include aluminum. The predetermined temperature may meet the T4 rating of UL 913. The explosion-proof detector assembly may further include a circular shaped electronic circuit board disposed inside the detector assembly enclosure configured to meet the standards of UL 913 and/or UL 1203. The circular shaped circuit board may be configured to prevent generation of sparks and ensure the predetermined temperature is never exceeded during one or more fault conditions.

### BRIEF DESCRIPTION OF THE SEVERAL VIEWS OF THE DRAWINGS

Other objects, features and advantages will occur to those skilled in the art from the following description of a preferred embodiment and the accompanying drawings, in which:

FIG. 1A is a three-dimensional front assembly view of one embodiment of the explosion-proof detector assembly for a FID of this invention;

FIG. 1B is a three-dimensional front-side view of the explosion-proof detector assembly shown in FIG. 1A fully assembled and showing an exemplary sample gas and a source of hydrogen;

FIG. 2A is a schematic side view showing a FID device having the explosion-proof detector assembly for an FID of this invention disclosed therein;

FIG. 2B is a three-dimensional front view of the FID device shown in FIG. 2A;

FIG. 3 is a schematic block diagram showing the typical operation of the FID shown in FIG. 1A;

FIG. 4A is a schematic side view showing in further detail the structure of the vent assembly shown in FIG. 1A;

FIG. 4B is a three-dimensional front view showing in further detail the structure of the sintered metal frit of the vent assembly shown in FIGS. 1A and 4A;

FIG. 5A is a schematic side view showing in further detail the structure of the sample line assembly shown in FIG. 1A;

FIG. 5B is a schematic three-dimensional front view showing in further detail the structure of the sintered metal frit shown in FIG. 5A;

FIG. 6A is a schematic side view showing in further detail the structure of the hydrogen line assembly shown in FIG. 1A;

FIG. 6B is a schematic three-dimensional front view showing in further detail the structure of the sintered metal frit shown in FIG. 6A;

FIG. 7A is a three-dimensional front view showing in further detail the structure of the electrical conduit assembly shown in FIG. 1A;

FIG. 7B is a schematic side view showing in further detail the structure of the wire spacer and composites of the electrical conduit assembly shown in FIGS. 1A and 7A;

FIG. 8A is a three-dimensional bottom view showing examples of the opening in the enclosure having internal threads for mating with the pressure relief assembly and the electrical conduit assembly shown in FIG. 1A;

FIG. 8B is a schematic front view showing the position of the openings shown in FIG. 8A;

FIG. 9A is a schematic side view showing in further detail the structure of the pressure relief assembly shown in FIG. 1A; and

FIG. 9B is a three-dimensional front view showing in further detail the structure of the sintered metal frit shown in FIG. 9A.

### DETAILED DESCRIPTION OF THE INVENTION

Aside from the preferred embodiment or embodiments disclosed below, this invention is capable of other embodiments and of being practiced or being carried out in various ways. Thus, it is to be understood that the invention is not limited in its application to the details of construction and the arrangements of components set forth in the following description or illustrated in the drawings. If only one embodiment is described herein, the claims hereof are not to be limited to that embodiment. Moreover, the claims hereof are not to be read restrictively unless there is clear and convincing evidence manifesting a certain exclusion, restriction, or disclaimer.

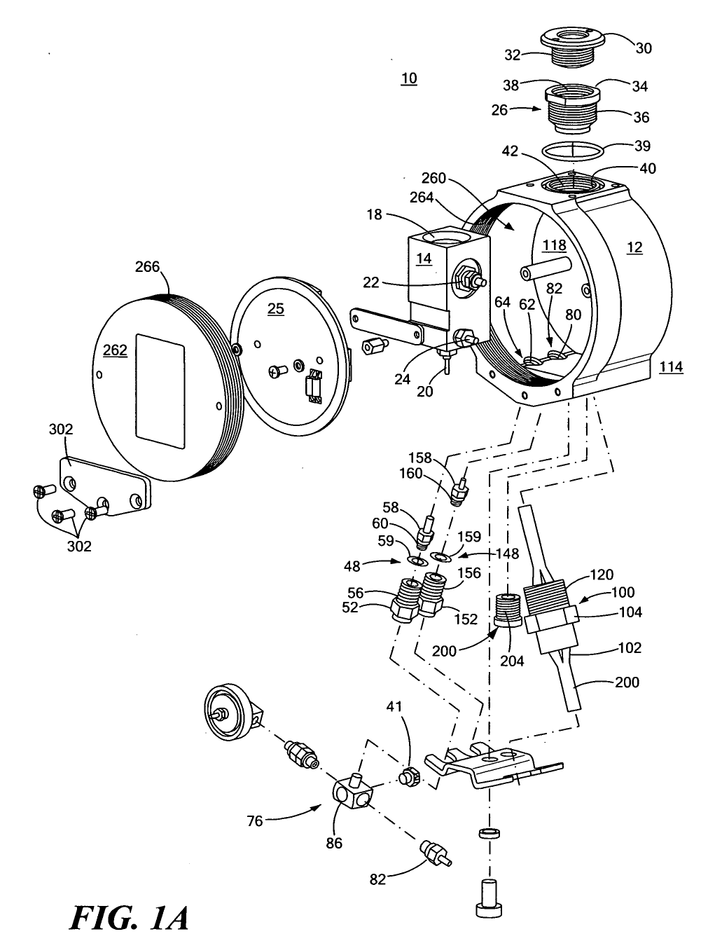

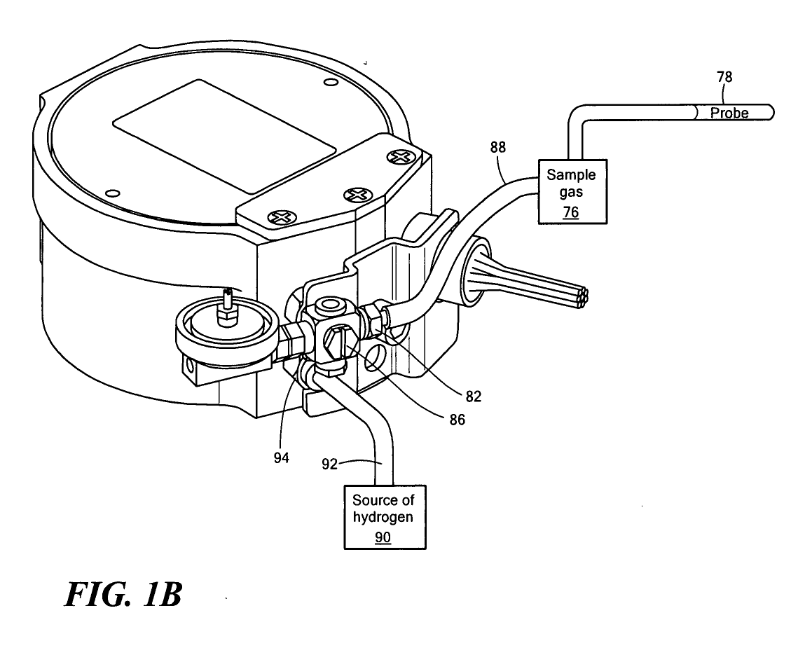

There is shown in FIG. 1A one embodiment of explosion-proof detector assembly 10 of this invention. Assembly 10 includes explosion-proof enclosure 12 which houses FID 14 therein. Enclosure 12 is preferably made of a non-ferrous material, such as aluminum or similar non-ferrous material. In one design, enclosure 12 has a minimum predetermined thickness throughout the entire enclosure which is preferably at least 0.125 inches +0.005 and −0.000 inches. This provides the ability for enclosure 12 to be explosion-proof in the event of one or more fault conditions inside enclosure 12 and to meet the T4 rating of UL 913, as discussed in further detail below.

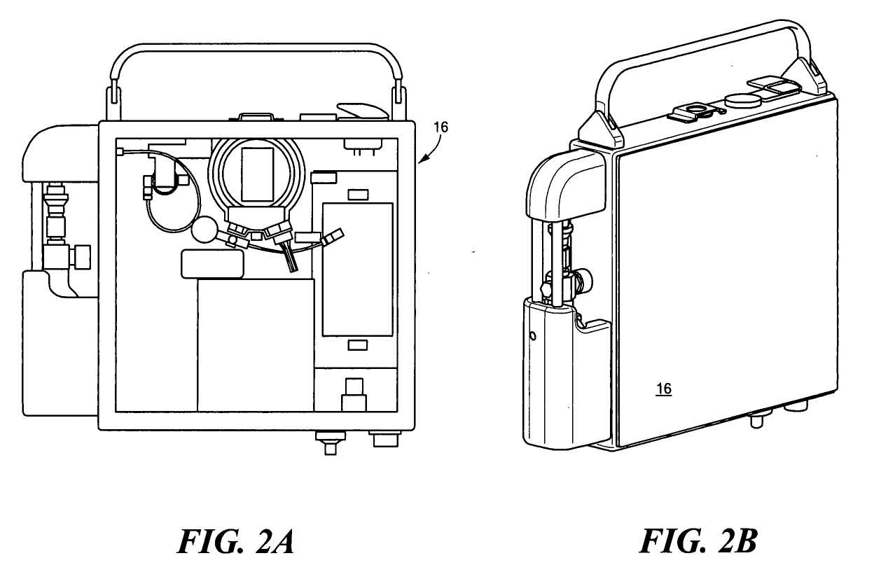

FID 14 is a key component of the FID device, e.g. FID device 16, FIGS. 2A and 2B, used to detect VOCs in LDAR applications and the like, as delineated in the Background section above. Therefore, in order to meet the standards of UL 913 and/or UL 1203 and be certified as intrinsically safe, FID 14, FIG. 1A is housed in explosion-proof enclosure 12. FID 14, itself is preferably certified as intrinsically safe and meets the requirements of UL 913 and/or UL 1203. In one example, FID 14 is manufactured by the assignee hereof, Photovac, Inc. (Waltham, Mass.). In other examples, an SRI FID, available from SRI Instruments (Torrance, Calif.), may be used. Using an SRI FID may require resizing of enclosure 12.

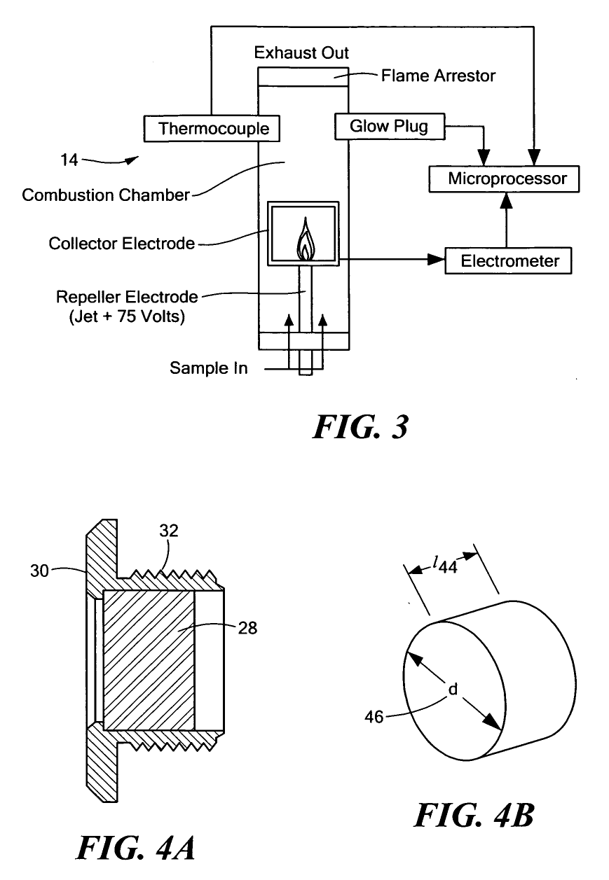

In operation, FID 14 utilizes a hydrogen flame contained in FID chamber 18. Hydrogen is introduced to detector chamber 18 via a fitting 20. A hydrogen flame is initiated (lit) via an ignitor 22 in FID chamber 18. A sample is drawn into the FID chamber 18 via fitting 24 via a pump (not shown). The sample encounters the hydrogen flame. VOCs (if present) are ionized when they encounter the flame. FID 14 has two electrodes inside chamber 18 (not shown). The flame jet is positively charged to a potential of about 100VDC, while the detector electrode is at 0V and connected to the input of a high gain current amplifier on circuit board 35. The burning of VOCs produces ions, which in turn creates a current flow between the electrodes, and ultimately become an analog voltage which is roughly proportional to the amount of VOCs present in the sample. Exhaust from FID 14 is continuously expelled to the outside environment continuously while FID 12 is in operation (discussed below). FID 14 responds to virtually all carbon containing compounds in vapor form which is measured by FID device 16, FIGS. 2A and 2B. FIG. 3 is a block diagram depicting the operation of FID 14.

The principal intrinsically safe compliance issues of explosion-proof assembly 10, FIG. 1A, involve the containment of two active sources of ignition present when operating FID 14 in a hazardous (e.g., explosive) environment. The two active sources of ignition are the ignitor 22 that is used to ignite the hydrogen and the hydrogen flame itself. Further, to satisfy the T4 intrinsic safety rating as mandated by UL 913, no surface of assembly 10 which is in contact with environment 114 can reach about 95° C. above ambient or be higher than about 135° C.

Because enclosure 12 is made of a non-ferrous material and has a minimum predetermined thickness throughout the entire enclosure as discussed above, enclosure 12 maintains its physical integrity and effectively contains any internal explosions therein that may occur during one or more fault conditions, e.g., damage from dropping the FID device or problems arising from component failure or an increase in pressure inside enclosure 12, such as a failure of the vent assembly, discussed below. Enclosure 12 also ensures all surfaces thereof meet the T4 rating. Thus, enclosure 12 meets the requirements of UL 913 and/or UL 1203.

Explosion-proof detector assembly 10 includes vent assembly 26 which includes sintered metal frit 28, FIG. 4A, which is preferably disposed in collar 30. In this example, collar 30 includes external threads 32. In one embodiment, vent assembly 26, FIG. 1A, may include adapter 34 which includes external threads 36 and internal threads 38. Internal threads 38 mate with external threads 32 on collar 30. External threads 36 on adapter 34 mate with internal threads 40 of opening 42 in enclosure 12. O-ring 39 is preferably disposed between enclosure 12 and the inside of the FID device. O-ring 39 forms a seal against ingress of rain or debris when the FID device is in use. External threads 32 on collar 32, external threads 36 and internal threads 38 of adapter 34, and internal threads 40 of opening 42 preferably have a predetermined class of fit, predetermined number of threads, and a predetermined thread depth to meet the requirements of UL 913 and/or UL 1203. In one embodiment, threads 32 of collar 30 and internal threads 38 of adapter 30 have a UNEF 3A class of fit, have 20 threads per inch, a thread depth of 0.375, and a minimum of 7.5 threads are engaged. In this example, external threads 36 of adapter 34 and internal threads 40 of opening 42 have a UNEF 3A class of fit, 20 threads per inch, a thread depth of 0.375 inches, and a minimum of 7.5 threads are engaged.

Sintered metal frit 28, FIG. 4A, preferably has a predetermined pore size, dimension, and flow rate to meet the standards of UL 913 and/or UL 1203. In this example, sintered metal frit 28 is made of 90 μm powdered stainless steel, has a length of about 0.375 inches, indicated at l-44, FIG. 4B, and a diameter of about 0.558 inches, indicated at d-46. Sintered metal frit 28 preferably has a flow rate of no less than about 500 mL/min at 0.2 psi. In one design, sintered metal frit 50 having the aforementioned porosity, dimensions and flow rate may be purchased from Mott Corporation (Farmington, Conn.).

Sintered metal frit 28 prevents a flame generated from FID 14, FIG. 1A, from contacting explosive atmosphere 114 outside enclosure 12 while allowing exhaust generated by the flame of FID 14 to vent to outside atmosphere 114. Sintered metal frit 28 also ensures that vent assembly 26 meets the T4 rating of UL 913. Sintered metal frit 28 also creates an explosion-proof seal in the event of one or more fault conditions within assembly enclosure 12. The result is vent assembly 26 meets the requirements of UL 913 and/or UL 1203 and can be certified as IS.

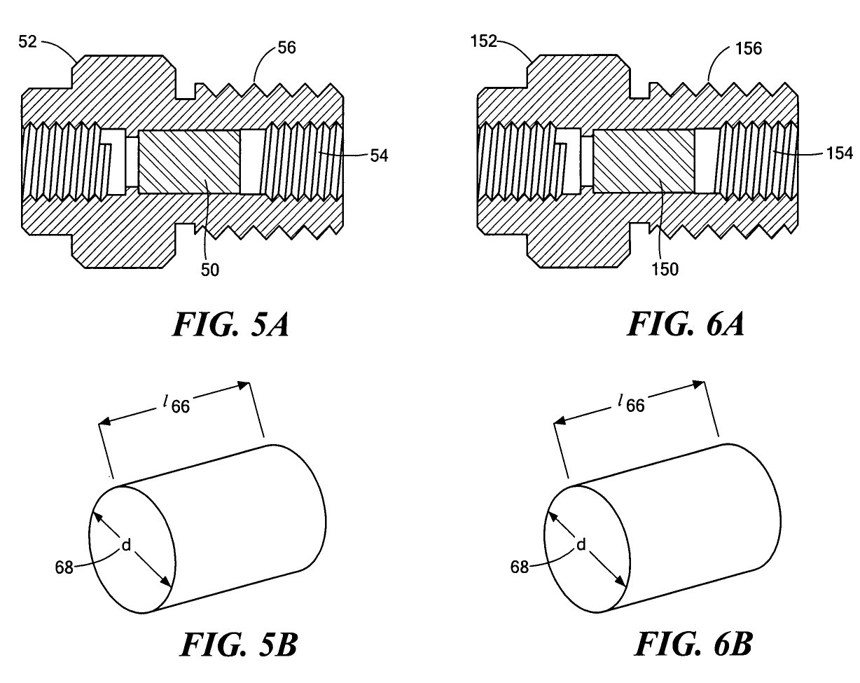

Explosion-proof detector assembly 10, FIG. 1A, further includes sample supply line assembly 48 which includes sintered metal frit 50, FIG. 5A, preferably housed in fitting 52. Fitting 52 includes internal threads 54 and external threads 56. Sample supply line assembly 48 also includes barbed fitting 58, FIG. 1A, which includes external threads 60 which mate with internal threads 56, FIG. 5A of fitting 52. O-ring 59, FIG. 1A, is typically disposed between fitting 52 and barbed fitting 58. External threads 56 of fitting 52 mate with internal threads in opening 64 in enclosure 12. Similar as discussed above, external threads 56 of fitting 52 which mate with internal threads 62 in opening 64 have a predetermined class of fit, predetermined number of threads, and a predetermined thread depth to meet the requirements of UL 913 and/or UL 1203. In one example, external threads 56 and internal threads 62 preferably have a UNC-3 class of fit, have 16 threads per inch, a thread depth of 0.375 inches and at least 6 threads are engaged to meet the requirements of UL 913 and/or UL 1203. Typically, internal threads 54, FIG. 5A, of fitting 52 are free of any sintered material and cleaned and re-tapped as needed to avoid the passage of unwanted solid debris into the detector system.

Sintered metal frit 50, FIG. 5A is preferably configured with a predetermined pore size, dimension, and flow rate to meet the standards of UL 913 and/or UL 1203. In this example, sintered metal frit 50 is made of stainless steel and has a minimum porosity of about 90 μm, a length, l-66, FIG. 5B, of about 0.250 inches, and a diameter, d-68, of about 0.151 inches. Preferably, sintered metal frit 50 has at a minimum flow rate of about 500 mL/min and 0.5 psi. In one design, sintered metal frit 50 having the aforementioned porosity, dimensions and flow rate may be purchased from Mott Corporation (Farmington, Conn.)

In operation, gaseous sample 76, FIG. 1B, to be tested is received from probe 78 exposed to the explosive atmosphere being tested. The sample is delivered via line 88 to fitting 82 coupled to manifold 84 which connects to fitting 52, FIG. 1A. The sample flows through sintered metal frit 50, FIGS. 5A and 5B, and is delivered to FID 14, FIG. 1A via fitting 24 on FID 14 and a tube (not shown). Sintered metal frit 50 is configured to allow the sample to flow there through and at the same time prevents a flame generated by FID 14 from contacting explosive atmosphere 114 outside assembly enclosure 12. Sintered metal frit also dissipates heat such that all surfaces of sample supply line assembly 48 meet the T4 rating of UL 913. Sintered metal frit 50 also creates an explosion-proof seal in the event of one or more fault conditions within assembly enclosure 12. The result is sample line assembly 48 meets the requirements of UL 913 and/or UL 1203 and can be certified as IS.

Explosion-proof detector assembly 10, FIG. 1A, further includes hydrogen line assembly 148 which includes sintered metal frit 150, FIG. 6A, preferably housed in fitting 152. Fitting 152 includes internal threads 154 and external threads 156. Hydrogen supply line assembly 148, FIG. 1A, also includes barbed fitting 158, which includes external threads 160 which mate with internal threads 156, FIG. 6A of fitting 152. O-ring 159, FIG. 1A, is typically disposed between fitting 152 and barbed fitting 158. External threads 156 of fitting 156 mate with internal threads 80 in opening 82 in enclosure 12. Similar, as discussed above, external threads 156 of fitting 152 which mate with internal threads 80 in opening 82 of enclosure 12 have a predetermined class of fit, predetermined number of threads, and a predetermined thread depth to meet the requirements of UL 913 and/or UL 1203. In one design, external threads 156 of fitting 152 and internal threads 80 of opening 82 preferably have a UNC-3 class of fit, have 16 threads per inch, a thread depth of 0.375 inches and at least 6 threads are engaged. Typically, internal threads 154, FIG. 6A, are free of any sintered material and cleaned and re-tapped as needed to avoid the passage of unwanted solid debris into the detector system.

Sintered metal frit 150, FIG. 6A, is preferably configured with a predetermined pore size, dimension, and flow rate to meet the standards of UL 913 and/or UL 1203. In this example, sintered metal frit 150 is made of stainless steel and has a minimum porosity of about 90 μm, a length, l-166, FIG. 6B of about 0.250 inches, and a diameter, d-168, of about 0.151 inches. Sintered metal frit 150 preferably has a minimum flow rate of about 500 mL/min at 0.5 psi. In one design, sintered metal frit having the aforementioned porosity, dimensions and flow rate may be purchased from Mott Corporation (Farmington, Conn.).

In operation, hydrogen is pumped from source of hydrogen 90, FIG. 1B, via line 92 coupled to fitting 94 which connects to fitting 152, FIG. 1A, including sintered metal frit 150, FIG. 6A. Hydrogen passes through sintered metal frit 150 and is delivered to FID 14, FIG. 1A, by a tube (not shown). Sintered metal frit 150 is configured to prevent a flame generated by FID 14 from contacting explosive atmosphere 114 outside assembly enclosure 12 and dissipates heat such that the temperature of hydrogen supply line assembly 148 meets the T4 rating of UL 913. Sintered metal frit 150 also creates an explosion-proof seal in the event of one or more fault conditions within assembly enclosure 12. The result is hydrogen line assembly 148 meets the requirements of UL 913 and/or UL 1203.

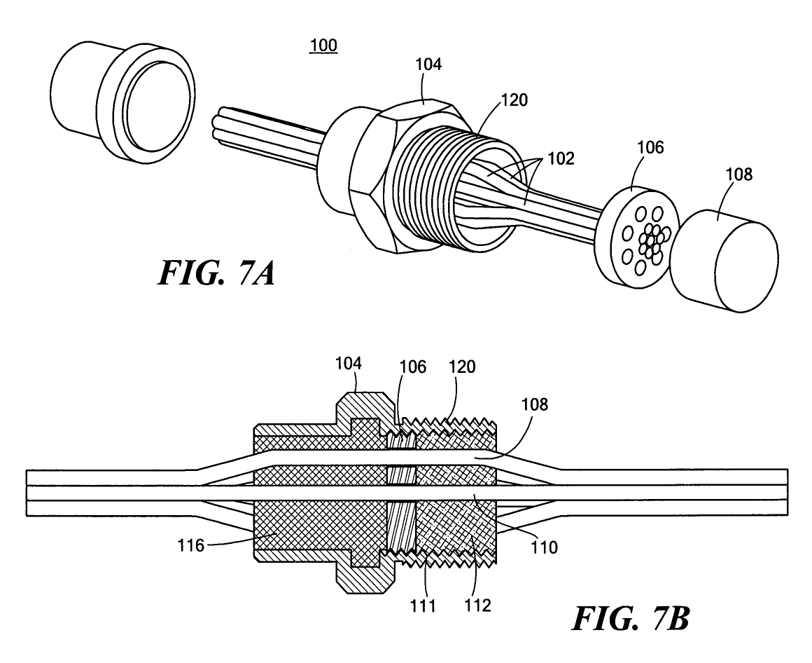

Explosion-proof detector assembly 10, FIG. 1A, further includes electrical conduit assembly 100 which houses a plurality of data communication and power wires 102. Electrical conduit assembly 100 preferably includes sleeve 104 which houses wire spacer 106, FIG. 7A. Spacer 106 spreads the plurality of data communication and power wires 102, e.g., exemplary wires 108 and 110, FIG. 7B. Spacer 106 is typically threaded into sleeve 104 via internal threads 111. Spacer 100 prevents arcing between the plurality of data and power wires 102 during one or more fault conditions. Electrical conduit assembly 100 also preferably includes composite 116 disposed on exterior atmospheric side 114, FIG. 1A, of detector assembly enclosure 12 and composite 112, FIG. 7B, of another predetermined type on interior side 118, FIG. 1A, of enclosure 12. In one example, composite 112 is a two part elastomeric flame retardant epoxy material, available from Hapco, Inc. (Hanover, Mass.). Composite 116 is a “concrete-like material”, e.g., made of fused calcium aluminate, plaster of paris, and quartz, such as CHICO® A, CHICO® X, and CHICO® AP Intrapak®, available from Cooper Crouse-Hinds (Syracuse, N.Y.). To meet the standards of UL 903 and/or UL 1203, CHICO® may be considered the material of choice for flame proof and explosion barriers. However, it was proven by testing that CHICO® was not the best material in terms of longevity when water is present. It turns out that water can be present within enclosure 12 as a natural byproduct of the combustion of the hydrogen by FID 14 within enclosure 12. This creates a humid environment within enclosure 12. Thus, composite 112 on inside 118 of enclosure 12 provides a water-proof barrier which prevents damage to composite 116.

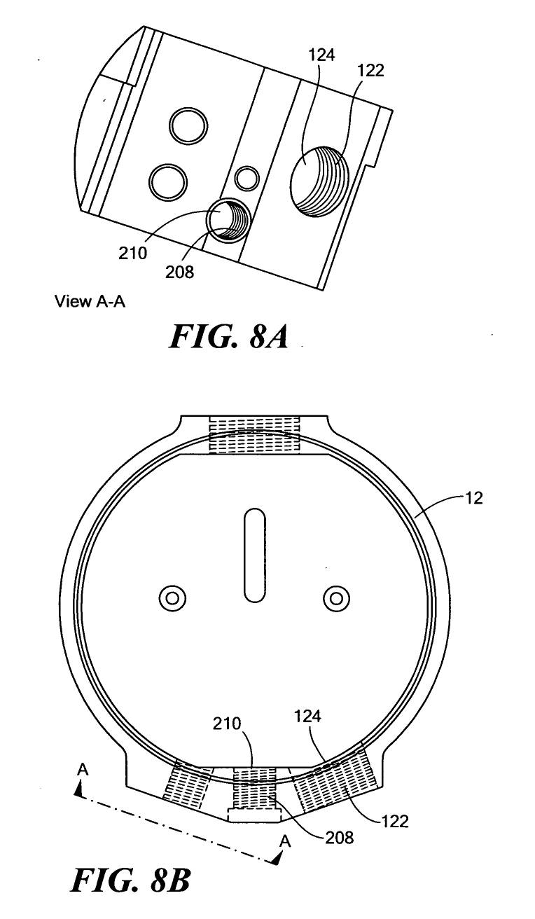

Electrical conduit assembly 100 also preferably includes external threads 120, FIGS. 1A, 7A and 7B which mate with internal threads 122, FIG. 8A, in opening 124 in enclosure 12 (also shown in FIG. 8B). In one embodiment, external threads 120 of sleeve 104 and internal threads 124 of opening 12 preferably have a predetermined class of fit, predetermined number of threads, and a predetermined thread depth to meet the requirements of UL 913 and/or UL 1203. In one embodiment, external threads 120 of sleeve 104 and internal threads 124 of opening 124 have a UNEF 3A class of fit, have 20 threads per inch, a thread depth of 0.389 inches, and a minimum of 7.5 threads are engaged.

The result is electrical conduit assembly 100 and prevents a flame generated by FID 14 from contacting explosive atmosphere 114, FIG. 1A, outside the detector assembly enclosure 12. Electrical conduit assembly 100 also dissipates heat such that the temperature of electrical conduit assembly 100 meets the T4 rating of UL 913. Electrical conduit assembly 100 also creates an explosion-proof seal in the event of one or more a fault condition within enclosure 12 to meet the requirements of UL 1203.

Enclosure 12, FIG. 1A, of explosion-proof detector assembly 10 has at least two venting systems. As discussed above, one venting system is vent assembly 26 which vents the combustive products of FID 14 to atmosphere 114 outside enclosure 12. Another is pressure relief assembly 200 which prevents a pressure build-up inside enclosure 12 in the event of one or more fault conditions.

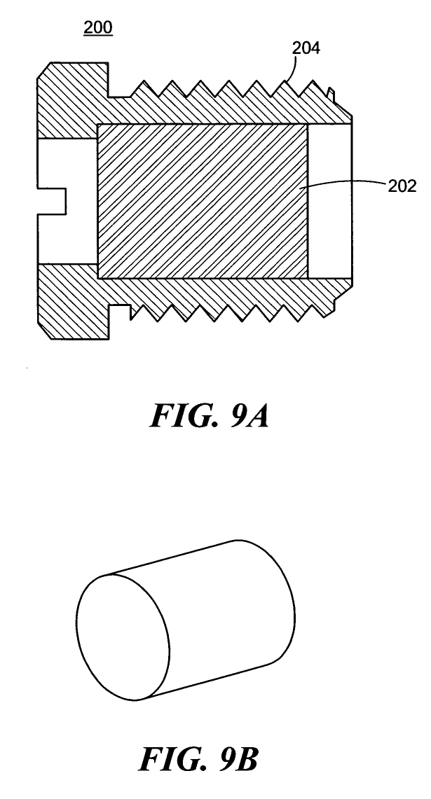

Pressure relief assembly 200 includes sintered metal frit 202, FIG. 9A, which ensures the pressure inside enclosure 12, FIG. 1A, does not exceed about 1 atm. Sintered metal frit 200 is also designed to prevent a flame generated by FID 14 from contacting explosive atmosphere 114 outside at assembly enclosure 12. Sintered metal frit 202 also dissipates heat such that the temperature of pressure relief assembly 26 meets the T4 rating of Ul 913. Sintered metal frit 202 also creates an explosion-proof seal in the event of a fault condition within assembly enclosure 12.

Pressure relief assembly 200, FIGS. 1A and 9A, also includes external threads 204 which mate with internal threads 208, FIG. 8A, in opening 210 in enclosure 12 (also shown in FIG. 8B). In one embodiment, external threads 204 of pressure relief assembly and internal threads 208 of opening 210 of enclosure 12 preferably have a predetermined class of fit, predetermined number of threads, and a predetermined thread depth to meet the requirements of UL 913 and/or UL 1203. In one embodiment, external threads 204 and internal threads 208 have a UNF 3A class of fit, have 20 threads per inch, a thread depth of 0.400 inches, and a minimum of 8 threads are engaged. The result is pressure relief assembly 200 meets the requirements of UL 913 and/or UL 1203.

In one design, explosion-proof detector assembly 10, FIG. 1A, includes circular shaped circuit board 250 disposed inside explosion proof enclosure 12. Board 250 is responsible for igniting ignitor 22, monitoring the temperature of the flame of FID 14, measuring VOC signals, generating and regulating of the voltage used to create the VOC signal, and the like. Circular shaped circuit board 250 preferably prevents generation of sparks and ensures the temperature that all components on board 250 meet the T4 rating during one or more fault conditions. Circular shaped circuit board 250 is intrinsically safe and meets the requirements of UL 913 and/or UL 1203. In one example, board 250 is manufactured by the assignee hereof, Photovac, Inc. (Waltham, Mass.).

Explosion-proof enclosure 12 preferably includes mechanical assembly opening 260 to which cover plate 262 is secured thereto. Preferably, cover plate 262 includes external threads 266 with mate with internal threads 264 of mechanical assembly opening 26. Internal threads 264 of mechanical assembly opening 260 and external threads 266 of cover 262 preferably each have a predetermined class of fit, number of threads, and thread depth to meet the requirement of UL 913 and/or UL 1203. In one example, internal threads 264 of opening 260 and external threads of cover 262 have a UNS-3B class of fit, have 18 threads per inch, a thread depth of about 0.400, and a minimum of 7.5 threads are engaged. Preferably, plate assembly 300 is secured to enclosure 12 with screws 302 to ensure cover 262 does not move. Thus, cover 262 and mechanical assembly opening 260 meet the requirements of UL 913 and/or UL 1203.

The result is the explosion-proof detector assembly 10 of one embodiment of this invention and meets the standards of UL 913 and/or UL 120 and can be certified as IS.

Although as discussed above with reference to FIGS. 1A-9B, the various threads of the vent assembly, hydrogen supply line assembly, sample line assembly, pressure relief assembly, electrical conduit assembly and the mechanical assembly opening and cover are each disclosed with an exemplary class of fit, number of threads and thread depth, this is not a necessary limitation of this invention. As known to those skilled in the art, the class of fit, number of threads and thread dept may be configured differently to meet the requirements of UL 913 and/or UL 1203. Typically one skilled in the art will refer to a Machinery's Handbook when manufacturing threads to meet a specific class of fit.

Additionally, the sintered metal fit of vent assembly, hydrogen supply line assembly, sample line assembly, and pressure relief assembly may each have different porosity, dimension, and minimum flow rates to meet UL 913 and/or UL 1203.

Although specific features of the invention are shown in some drawings and not in others, this is for convenience only as each feature may be combined with any or all of the other features in accordance with the invention. The words “including”, “comprising”, “having”, and “with” as used herein are to be interpreted broadly and comprehensively and are not limited to any physical interconnection. Moreover, any embodiments disclosed in the subject application are not to be taken as the only possible embodiments.

In addition, any amendment presented during the prosecution of the patent application for this patent is not a disclaimer of any claim element presented in the application as filed: those skilled in the art cannot reasonably be expected to draft a claim that would literally encompass all possible equivalents, many equivalents will be unforeseeable at the time of the amendment and are beyond a fair interpretation of what is to be surrendered (if anything), the rationale underlying the amendment may bear no more than a tangential relation to many equivalents, and/or there are many other reasons the applicant can not be expected to describe certain insubstantial substitutes for any claim element amended.

Other embodiments will occur to those skilled in the art and are within the following claims.

What is claimed is:

1. An explosion-proof detector assembly for a flame ionization detector (FID) comprising:
an explosion-proof detector assembly enclosure configured to house the FID therein;
a vent assembly coupled to the assembly enclosure including a sintered metal frit configured to allow exhaust generated by the FID to vent from the detector assembly enclosure;
a hydrogen supply line assembly coupled to the assembly enclosure including a sintered metal frit configured to deliver a supply of hydrogen to the FID;
a sample line assembly coupled to the enclosure including a sintered metal frit configured to deliver a sample gas to the FID;
a pressure relief assembly coupled to the assembly enclosure including a sintered metal frit configured to ensure the pressure inside the detector assembly enclosure does not exceed a predetermined pressure;
wherein the sintered metal frit of the vent assembly, the hydrogen supply line assembly, the sample line assembly, and the pressure relief assembly are each configured to: prevent a flame generated by the FID from contacting an explosive atmosphere outside the assembly enclosure, dissipate heat such that the temperature thereof does not exceed a predetermined temperature, and create an explosion-proof seal; and
an electrical conduit assembly configured to house a plurality of data communication and power wires and configured to prevent a flame generated by the FID from contacting an explosive atmosphere outside the detector assembly enclosure, dissipate heat such that the temperature of all surfaces thereof do not exceed a predetermined temperature, and create an explosion-proof seal.

2. The explosion-proof detector assembly of claim 1 in which the explosion-proof detector assembly is configured to meet the standards of UL 913 and/or UL 1203.

3. The explosion-proof detector assembly of claim 1 in which the detector assembly enclosure includes a plurality of openings each having internal threads.

4. The explosion-proof detector assembly of claim 3 in which the vent assembly includes a collar configured to house the sintered metal frit of the vent assembly therein.

5. The explosion-proof detector assembly of claim 4 in which the vent assembly includes an adapter including internal threads for mating with external threads of the collar and external threads for mating with internal threads of one of the plurality of openings of the detector assembly enclosure.

6. The explosion-proof detector assembly of claim 5 in which the external threads of the collar, the internal and external threads of the adaptor, and the internal threads of the one of the plurality of openings of the detector assembly enclosure each have a predetermined class of fit, a predetermined number of threads, and a predetermined thread depth configured to meet the requirements of UL 913 and UL 1203.

7. The explosion-proof detector assembly of claim 6 in which the sintered metal frit of the vent assembly is configured with a predetermined pore size, dimension, and flow rate to meet the standards of UL 913 and/or UL 1203.

8. The explosion-proof detector assembly of claim 3 in which the hydrogen supply line assembly includes a fitting configured to house the sintered metal frit of the hydrogen supply line assembly therein.

9. The explosion-proof detector assembly of claim 8 in which the fitting assembly includes a external threads for mating with the internal threads of one of the plurality of openings of the detector assembly enclosure.

10. The explosion-proof detector assembly of claim 9 in which the external threads of the fitting and the internal threads of the one of the plurality of openings of the detector assembly enclosure each have a predetermined class of fit, number of threads, and thread depth configured to meet the standards of UL 913 and/or UL 1203.

11. The explosion-proof detector assembly of claim 10 in which the sintered metal frit of the hydrogen supply line assembly is configured with a predetermined pore size, dimension, and flow rate to meet the standards of UL 913 and/or UL 1203.

12. The explosion-proof detector assembly of claim 3 in which the sample line assembly includes a fitting having internal threads configured to house the sintered metal thread therein.

13. The explosion-proof detector assembly of claim 12 in which the fitting includes external threads for mating with internal threads of one of the plurality of openings of the detector assembly enclosure.

14. The explosion-proof detector assembly of claim 13 in which the external threads of the fitting and the internal threads of the one of the plurality of openings of the detector assembly enclosure each have a predetermined class of fit, number of threads, and thread depth configured to meet the standards of UL 913 and/or UL 1203.

15. The explosion-proof detector assembly of claim 12 in which the sintered metal frit of the sample line assembly is configured with a predetermined pore size, dimension, and flow rate to meet the standards of UL 913 and/or UL 1203.

16. The explosion-proof detector assembly of claim 1 in which the electrical conduit assembly includes a sleeve coupled to the detector assembly enclosure and a wire spacer for spreading a plurality of data communication and power wires in the sleeve and a composite of one predetermined type on the exterior atmospheric side of the detector assembly enclosure and another composite of another predetermined type on the interior side of the detector assembly enclosure configured to meet the standards of UL 913 and UL 1203.

17. The explosion-proof detector assembly of claim 16 in which the composite on the interior side of the detector assembly enclosure is configured to prevent moisture inside the enclosure from damaging the composite on the exterior atmosphere side of the detector assembly enclosure.

18. The explosion-proof detector assembly of claim 16 in which the spacer is configured to prevent arcing of the data communication and power wires in the event of one or more fault conditions.

19. The explosion-proof detector assembly of claim 16 in which the sleeve of the electrical conduit assembly includes external threads for mating with the internal threads of one of the plurality of openings of the detector assembly enclosure.

20. The explosion-proof detector assembly of claim 19 in which the external threads of the sleeve and the internal threads of the one of the plurality of openings of the detector assembly enclosure each have a predetermined class of fit, number of threads, and thread depth configured to meet the standards of UL 913 and/or UL 1203.

21. The explosion-proof detector assembly of claim 1 in which the detector assembly enclosure includes a mechanical assembly opening and a cover plate securably attached thereto.

22. The explosion-proof detector assembly of claim 21 in which the mechanical assembly opening includes internal threads and the cover plate includes external threads for mating with the internal threads of the mechanical opening.

23. The explosion-proof detector assembly of claim 22 in which the internal threads of the mechanical assembly opening and the external threads of the cover each have a predetermined class of fit, number of threads, and thread depth configured to meet the standards of UL 913 and/or UL 1203.

24. The explosion-proof detector assembly of claim 1 in which the detector assembly enclosure has a minimum predetermined thickness configured to provide an explosion-proof seal and meet the standards of UL 913 and/or UL 1203.

25. The explosion-proof detector assembly of claim 21 in which the cover has a minimum predetermined thickness configured to provide an explosion-proof seal and configured to meet the standards of UL 913 and/or UL 1203.

26. The explosion-proof detector assembly of claim 1 in which the detector assembly enclosure is made of a non-ferrous material.

27. The explosion-proof detector assembly of claim 25 in which the non-ferrous material includes aluminum.

28. The explosion-proof detector assembly of claim 1 in which the predetermined temperature meets the T4 rating of UL 913.

29. The explosion-proof detector assembly of claim 1 further including a circular shaped electronic circuit board disposed inside the detector assembly enclosure configured to meet the standards of UL 913 and/or UL 1203.

30. The explosion-proof detector assembly of claim 28 in which the circular shaped circuit board is configured to prevent generation of sparks and ensure the predetermined temperature is never exceeded during one or more fault conditions.
